(19) United States
(12) Patent Application Publication
(10) Pub. No.: US 2023/0378190 A1
(43) Pub. Date: Nov. 23, 2023

(54) SEMICONDUCTOR DEVICE

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 17/747,058

(22) Filed: May 18, 2022

(51) Int. Cl. H01L 27/12

(52) U.S. Cl. CPC H01L 27/124; H01L 27/1222

(57) ABSTRACT

Semiconductor devices are provided. A logic cell includes P-type GAA nanosheet transistor and N-type GAA nanosheet transistor. Each of the P-type and N-type GAA nanosheet transistors has two channel members vertically stacked. A back-side interconnect structure includes first and second back-side contacts, a VDD line formed in a back-side metal layer and coupled to a source feature of the P-type GAA nanosheet transistor through the first back-side contact, and a VSS line formed in the back-side metal layer and coupled to a source feature of the N-type GAA nanosheet transistor through the second back-side contact. A front-side interconnect structure includes first and second front-side contacts, and a metal line coupled to a drain feature of the P-type GAA nanosheet transistor through the first front-side contact or coupled to a drain feature of the N-type GAA nanosheet transistor through the second front-side contact.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) transistors have been incorporated into memory devices (including, for example, static random-access memory, or SRAM, cells) and core devices (including, for example, standard logic, or STD, cells) to reduce chip footprint while maintaining reasonable processing margins.

However, as GAA transistors and circuit cells continue to be scaled down, VDD and VSS power routing uses too many routing resources and therefore impact the cell scaling as well as cell performance. Accordingly, although existing technologies for fabricating circuit cells including GAA transistors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various nodes are not drawn to scale. In fact, the dimensions of the various nodes may be arbitrarily increased or reduced for clarity of discussion.

FIG. 1A shows the logic symbol of the standard cell NAND.

FIG. 1B shows a circuit diagram of the standard cell NAND in FIG. 1A.

FIG. 2A shows the logic symbol of the standard cell INV (i.e., inverter).

FIG. 2B shows a circuit diagram of the standard cell INV in FIG. 2A.

FIG. 3 shows a cross sectional view of a GAA transistor, in accordance with some embodiments of the disclosure.

FIG. 4 shows a cross sectional view of a semiconductor device, in accordance with some embodiments of the disclosure.

FIGS. 5A and 5B show top views (or layouts) of a semiconductor device, in accordance with some embodiments of the disclosure.

FIG. 6A shows a cross sectional view of the semiconductor device along a line A-AA in FIGS. 5A and 5B, in accordance with some embodiments of the disclosure.

FIG. 6B shows a cross sectional view of the semiconductor device along a line B-B in FIGS. 5A and 5B, in accordance with some embodiments of the disclosure.

FIG. 6C shows a cross sectional view of the semiconductor device along a line C-CC in FIGS. 5A and 5B, in accordance with some embodiments of the disclosure.

FIG. 6D illustrates a cross sectional view of an embodiment of the semiconductor device along a line D-DD in FIGS. 5A and 5B, in accordance with some embodiments of the disclosure.

FIG. 6E shows a cross sectional view of the semiconductor device along a line E-EE in FIGS. 5A and 5B, in accordance with some embodiments of the disclosure.

FIGS. 7A through 7C shows cross sectional views of the connection structures (or power tap structure) for connecting the VDD or VSS voltage line of the back-side interconnect structure to the VDD or VSS voltage source of the front-side interconnect structure, in accordance with some embodiments of the disclosure.

### DETAILED DESCRIPTION

The following disclosure provides many different embodiments, or examples, for implementing different nodes of the subject matter provided. Specific examples of components and arrangements are described below to simplify the present disclosure. These are, of course, merely examples and are not intended to be limiting. In some embodiments, the formation of a first node over or on a second node in the description that follows may include embodiments in which the first and the second nodes are formed in direct contact, and may also include embodiments in which additional nodes may be formed between the first and the second nodes, such that the first and the second nodes may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

Furthermore, spatially relative terms, such as “beneath,” “below,” “lower,” “above,” “upper” and the like, may be used herein for ease of description to describe one element or feature's relationship to another element or feature as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to circuit cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it should be understood that other embodiments may offer different advantages, not all advantages are necessarily discussed herein, and no particular advantage is required for all embodiments. The details of the present disclosure are described below in conjunction with the accompanying drawings, which illustrate the layout and structure of logic cells, according to some embodiments.

In an integrated circuit (IC), a logic circuit is configured to perform a specific function or operation. The logic circuit includes multiple logic cells. In some embodiments, the logic cell may be a standard cell (STD cell). In such embodiments, the logic cells form a cell array, and the logic cells have the same cell height. In some embodiments, the cell array is capable of performing a specific function. In some embodiments, the logic cells is capable of performing various functions. In some embodiments, the logic cells are the standard cells (e.g., inverter (INV), AND, OR, NAND, NOR, Flip-Flop, SCAN, etc.), a combination thereof or specific functional cells. Furthermore, each logic cell includes multiple transistors, i.e., PMOS and NMOS transistors. In some embodiments, the logic cells corresponding to the same function or operation may have the same circuit configuration.

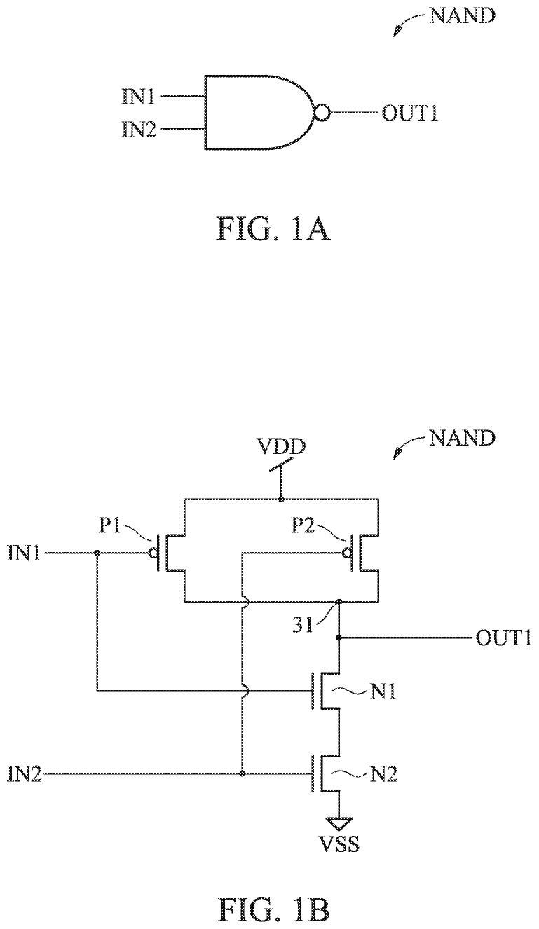

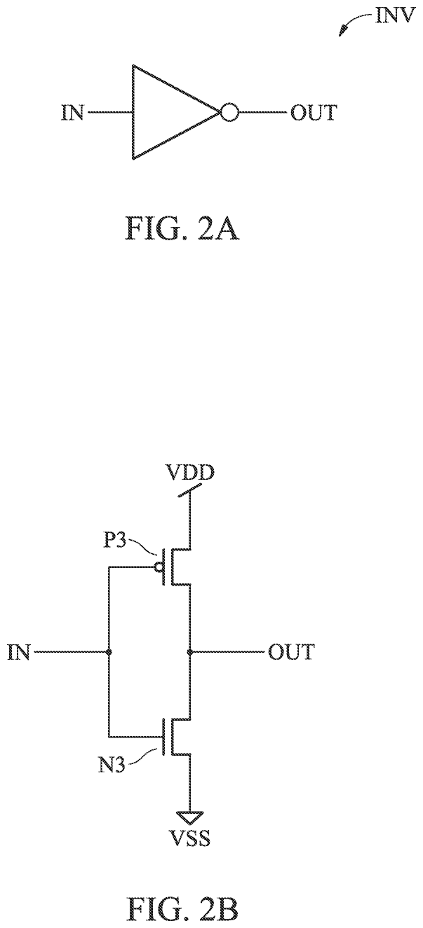

FIG. 1A shows the logic symbol of the standard cell NAND. FIG. 1B shows a circuit diagram of the standard cell NAND in FIG. 1A. The standard cell NAND is a logic gate configured to provide an output signal OUT1 according two input signals IN1 and IN2. The standard cell NAND includes two PMOS transistors P1 and P2 and two NMOS transistors N1 and N2. In some embodiments, the two PMOS transistors P1 and P2 and two NMOS transistors N1 and N2 are gate-all-around (GAA) field effect transistors (FETs).

In the standard cell NAND, the PMOS transistors P1 and P2 are coupled in parallel between a node 31 and a power supply VDD. The NMOS transistor N1 is coupled between the node 31 and the NMOS transistor N2, and the NMOS transistor N2 is coupled between the NMOS transistor N1 and a ground VSS. The input signal IN1 is input to the gates of the PMOS transistor P1 and the NMOS transistor N1, and the input signal IN2 is input to the gates of the PMOS transistor P2 and the NMOS transistor N2. Furthermore, the output signal OUT1 is provided at the node 31.

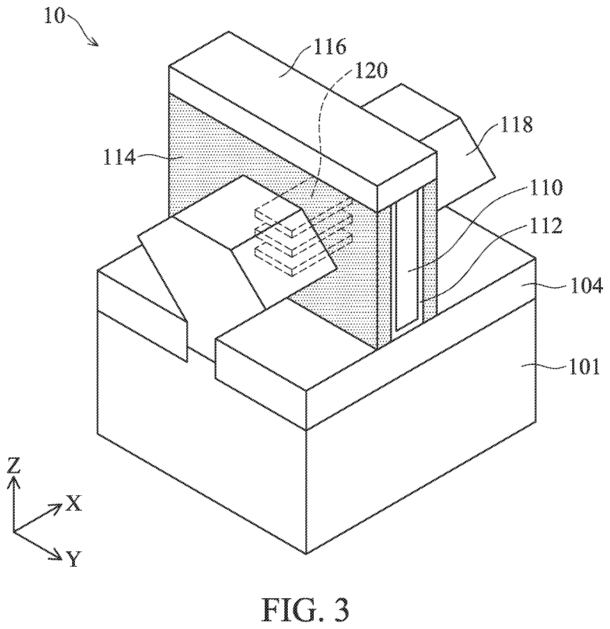

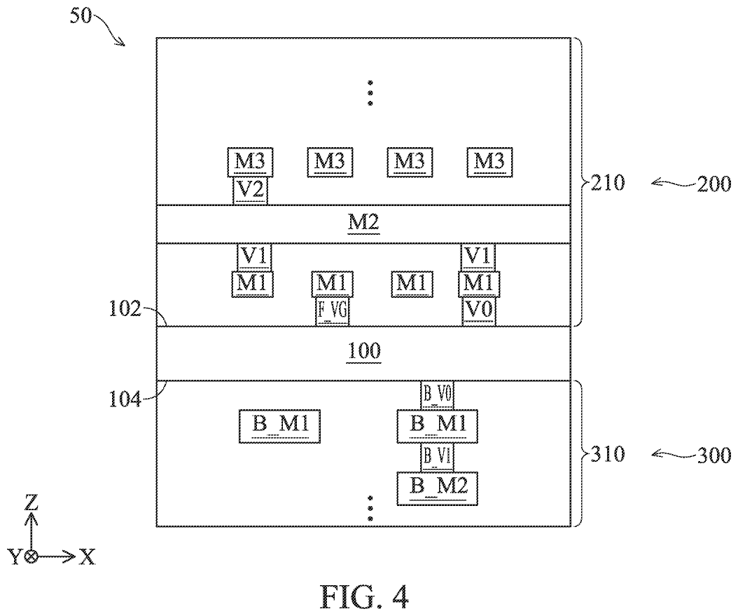

FIG. 2A shows the logic symbol of the standard cell INV (i.e., inverter). FIG. 2B shows a circuit diagram of the standard cell INV in FIG. 2A. The standard cell INV is a logic gate configured to inverting an input signal IN to provide an output signal OUT1. The standard cell INV includes a PMOS transistor P3 and an NMOS transistor N3. In some embodiments, the PMOS transistor P3 and the NMOS transistor N3 are the GAA FETs.

In the standard cell INV, the PMOS transistor P3 is coupled between the NMOS transistor N3 and a power supply VDD. The NMOS transistor N3 is coupled between the PMOS transistor P3 and a ground VSS. The input signal IN is input to the gates of the PMOS transistor P3 and the NMOS transistor N3. Furthermore, the output signal OUT is provided at the drains of the NMOS transistor N3 and the PMOS transistor P3.

Compared with the FinFET transistors that have a fin bottom portion out of gate control problem and therefore limited the continue shrunk capability, the GAA FETs allows for more aggressive gate length scaling for both performance and density improvement. The GAA FET has vertically-stacked horizontal semiconductor nanowires/nanosheets with extremely narrow cylindrical or sheet channel body. Due to better gate control ability, lower leakage current, shrink capability and fully FinFET device layout comparable, the GAA FET has become a best candidate for future generation and low supply voltage applications. Furthermore, the GAA FET formed by semiconductor nanosheet has wider channel width for high speed application.

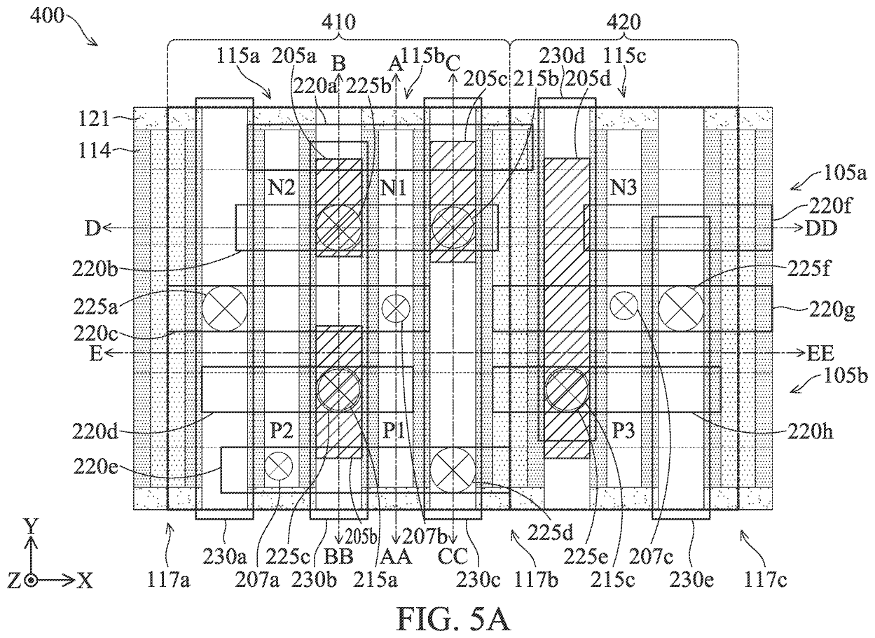

Each of the circuit cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that the application should not be limited to a particular type of device, except as specifically claimed.

Referring to FIG. 3, a perspective view of an exemplary GAA transistor 10 is illustrated. The GAA transistor 10 includes a substrate 101. The substrate 101 may contains a semiconductor material, such as bulk silicon (Si). In some other embodiments, the substrate 101 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 101 may also include an insulating layer, such as a silicon oxide layer, to have a silicon-on-insulator (SOI) structure or a germanium-on-insulator (GOI) structure. In some embodiments, after the resultant GAA transistor 10 is formed, the substrate 101 may be removed by a suitable process (e.g., a chemical mechanical polishing (CMP) process) for forming back-side interconnections.

The GAA transistor 10 also includes one or more nanostructures 120 (dash lines) extending in an X-direction and vertically arranged (or stacked) in a Z-direction. More specifically, the nanostructures 120 are spaced from each other in the Z-direction. In some embodiments, the nanostructures 120 may also be referred to as channels, channel layers, nanosheets, or nanowires. The nanostructures 120 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 120 include silicon for N-type GAA transistors. In other embodiments, the nanostructures 120 include silicon germanium for P-type GAA transistors. In some embodiments, the nanostructures 120 are all made of silicon, and the type of GAA transistors depend on work function metal layer wrapping around the nanostructures 120.

The GAA transistor 10 further includes a gate structure including a gate electrode 110 and a gate dielectric layer 112. The gate dielectric layer 112 wraps around the nanostructures 120 and the gate electrode 110 wraps around the gate dielectric layer 112 (not shown). The gate electrode 110 may include polysilicon or work function metal. The work function metal includes TiN, TaN, TiAl, TiAlN, TaAl, TaAlN, TaAlC, TaCN, WNC, Co, Ni, Pt, W, combinations thereof, or other suitable material.

In some embodiments, the gate electrode 110 may include a capping layer, a barrier layer, an n-type work function metal layer, a p-type work function metal layer, and a fill material (not shown). In some embodiments, the P-type transistors and the N-type transistors are formed by the same work function material. In some embodiments, the P-type transistors and the N-type transistors are made of different work function materials.

The gate dielectric layer 112 may include dielectric materials, such as silicon oxide, silicon nitride, silicon oxynitride, dielectric material(s) with high dielectric constant (high-k), or a combination thereof. Examples of high-k dielectric materials include TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material.

As shown in FIG. 3, the gate spacers 114 are on sidewalls of the gate dielectric layer 112 and over the nanostructures 120 (not shown). The gate spacers 114 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 114 may include a single layer or a multi-layer structure.

The gate top dielectric layer 116 is over the gate dielectric layer 112, the gate electrode 110, and the nanostructures 120. The gate top dielectric layer 116 is used for contact etch protection layer. The material of gate top dielectric layer 116 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material. The thickness of the gate top dielectric layer 116 about 2 nm to about 60 nm.

The GAA transistor 10 further includes epitaxially-grown materials 118. As shown in FIG. 3, two epitaxially-grown materials 118 are on opposite sides of the gate structure. The epitaxially-grown materials 118 serve as the source/drain features of the GAA transistor 10. Therefore, the epitaxially-grown materials 118 may also be referred to as source/drain, source/drain features, or source/drain nodes. In some embodiments, for an N-type GAA transistor, the epitaxially-grown materials 118 may include SiP, SiC, SiPC, SiAs, Si, or a combination thereof. Furthermore, the Phosphorus (or Arsenic, or both) doping concentration of the source/drain features of the N-type GAA transistor about 2e19/cm⁻³ to about 3e21/cm⁻³. In some embodiments, for a P-type GAA transistor, the epitaxially-grown materials 118 may include SiGe, SiGeC, Ge, Si, a boron-doped SiGe, boron and carbon doped SiGe, or a combination thereof. Moreover, the Boron doping concentration of source/drain features of the P-type GAA transistor about 1e19/cm⁻³ to about 6e20/cm⁻³.

The nanostructures 120 (dash lines) extends in an X-direction to connect two epitaxially-grown materials 118. Such the nanostructures 120 and the epitaxially-grown materials 118 connected continuously with each other may be collectively referred to as an active area.

Isolation feature 104 is over the substrate 101 and under the gate dielectric layer 112, the gate electrode 110, and the gate spacers 114. The isolation feature 104 is used for isolating the GAA transistor 10 from other devices. In some embodiments, the isolation feature 104 may include different structures, such as shallow trench isolation (STI) structure, deep trench isolation (DTI) structure. Therefore, the isolation feature 104 is also referred as to as a STI feature or DTI feature.

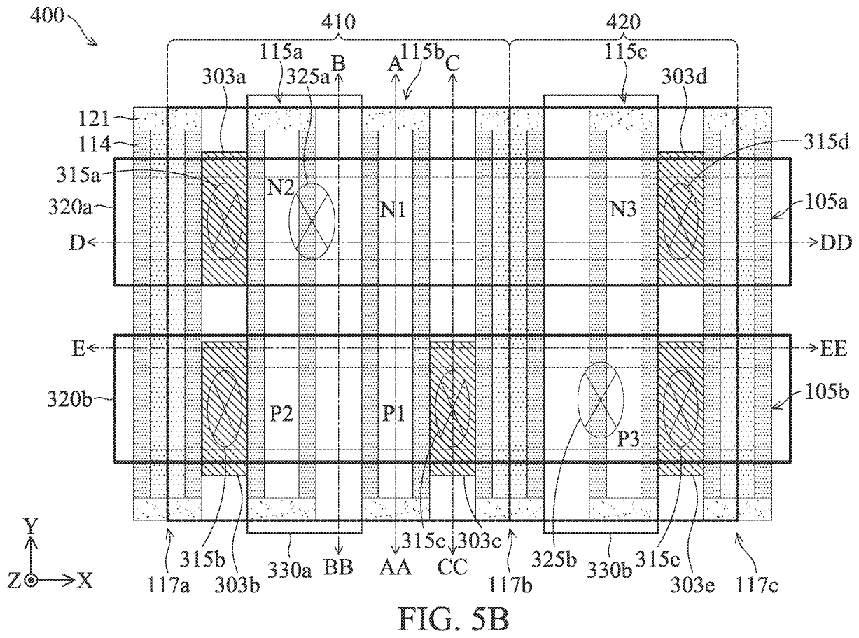

FIG. 4 shows a cross sectional view of a semiconductor device 50, in accordance with some embodiments of the disclosure. The semiconductor device 50 has a device region 100 (also referred to as a device layer), a front-side interconnect structure 200, and a back-side interconnect structure 300. The device region 100 is the region where the transistors and the main features are located, such as the gate, channel, source/drain, contact features, and the transistors (e.g., the N-type transistors N1 to N3, and the P-type transistors P1 to P3) of the logic cells discussed above. The device region 100 has a front side 102 and a back side 104.

The back-side interconnect structure 300 is under the device region 100 or at the back side 104 of the device region 100, and the front-side interconnect structure 200 is over the device region 100 or at the front side 102 of the device region 100. The back-side interconnect structure 300 includes an inter-metal dielectric (IMD) 310, the vias B_V0, B_V1, and the metal lines B_M1, B_M2. The front-side interconnect structure 200 includes the IMD 210, the vias F_VG, V0, V1, V2, and the metal lines M1, M2, M3. The vias and metal lines in the IMD 310 and the IMD 210 are electrically coupled to various transistors (e.g., the N-type transistors N1 to N3, and the P-type transistors P1 to P3, other transistors) and/or components (e.g., the gate, source/drain features, resistors, capacitors, and/or inductors) in the device region 100, such that the various devices and/or components can operate as specified by design requirements of logic cell (e.g., INV, NAND, NOR, flip-flop, SCAN, other logic cells, or other STD cells). It should be noted that there may be more vias and metal lines in the IMD 210 and the IMD 310 for connections. The IMD 210 and 310 may be multilayer structure, such as one or more dielectric layers.

The back-side interconnect structure 300 is at the back side 104 of the device region 100, the IMD 310, the vias B_V0, B_V1, and the metal lines B_M1, B_M2 may also be referred to as the back-side IMD, the back-side vias, and the back-side metal lines, respectively. Similarly, the front-side interconnect structure 200 is at the front side 102 of the device region 100, the IMD 210, the vias F_VG, V0, V1, V2, and the metal lines M1, M2, M3 may also be referred to as the front-side IMD, the front-side vias, and the front-side metal lines, respectively.

In some embodiments, the via F_VG is connected to the gate structures (gate electrodes) of the transistors. Therefore, the via F_VG is also referred to as the gate via, or respectively referred to as the front-side gate via. In some embodiments, the vias and metal lines in the IMD 310 are used for the connections of the features of the transistor.

In some embodiments, the vias and metal lines in the IMD 310 are connected to voltage sources (or power sources) (not shown) to provide voltage to the transistors in the device region 100. Therefore, the metal lines (e.g., the metal lines B_M1, B_M2) in the IMD 310 may be also referred to as the voltage metal lines, the voltage lines, or voltage conductors.

The formation of the back-side interconnect structure 300 may include removing the substrate (if present) in a CMP process, forming a back-side dielectric layer (not shown) under the device region 100, and forming back-side contacts (not shown) connected to the source features in the device region 100 in the back-side dielectric layer. The formation of the back-side interconnect structure 300 may further include forming a first dielectric layer of the IMD 310 under the back-side dielectric layer, forming back-side first level vias (e.g., the vias B_V0) in the first dielectric layer, and forming a second dielectric layer of the IMD 310 under the first dielectric layer. The formation of the back-side interconnect structure 300 may further include forming back-side first level metal lines (e.g., the metal lines B_M1) in the second dielectric layer, forming a third dielectric layer of the IMD 310 under the second dielectric layer, forming back-side second level vias (e.g., the via B_V1) in the third dielectric layer. The formation of the back-side interconnect structure 300 may further include forming a fourth dielectric layer of the IMD 310 under the third dielectric layer, forming back-side second level metal lines (e.g., the metal line B_M2) in the fourth dielectric layer, and forming protection layer (may be multiple layers and include dielectric layers, poly layers, or combination) under the fourth dielectric layer.

The formation of the front-side interconnect structure 200 is similar to that of the back-side interconnect structure 300, the difference being that the formation processes of the front-side interconnect structure 200 are performed at the front side 102 of the device region 100, and they are not described in detail herein.

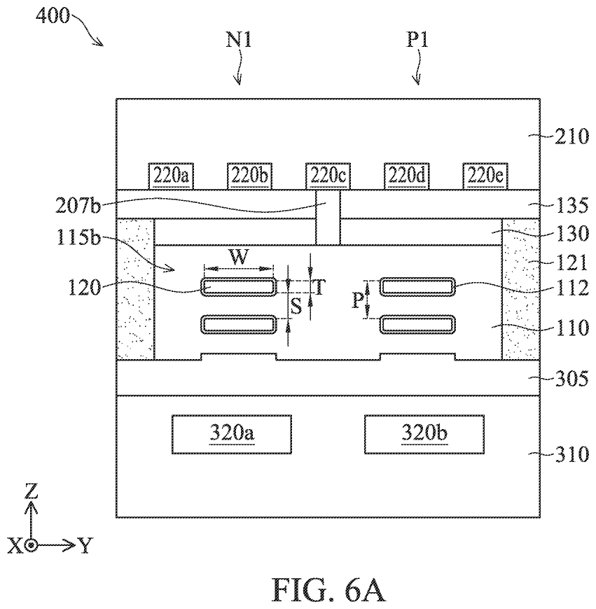

FIGS. 5A and 5B show top views (or layouts) of a semiconductor device 500, in accordance with some embodiments of the disclosure. FIG. 5A illustrates the features in the device region (including transistors) and the front-side interconnect structure (including vias and metal lines), and FIG. 5B illustrates the features in the device region and the back-side interconnect structure.

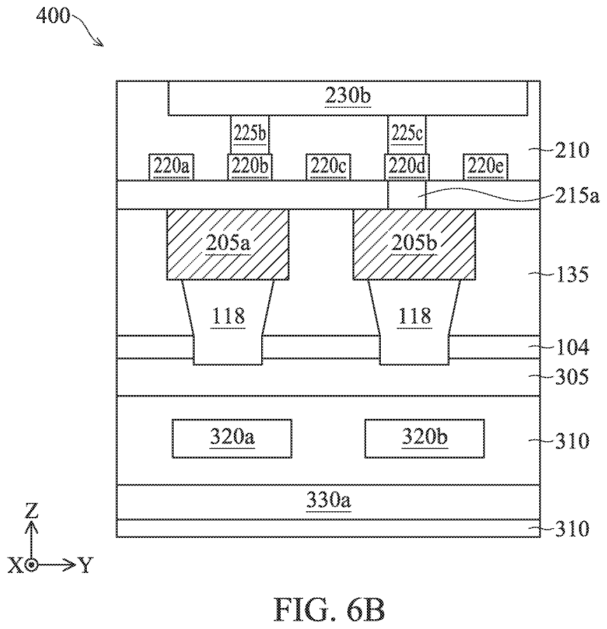

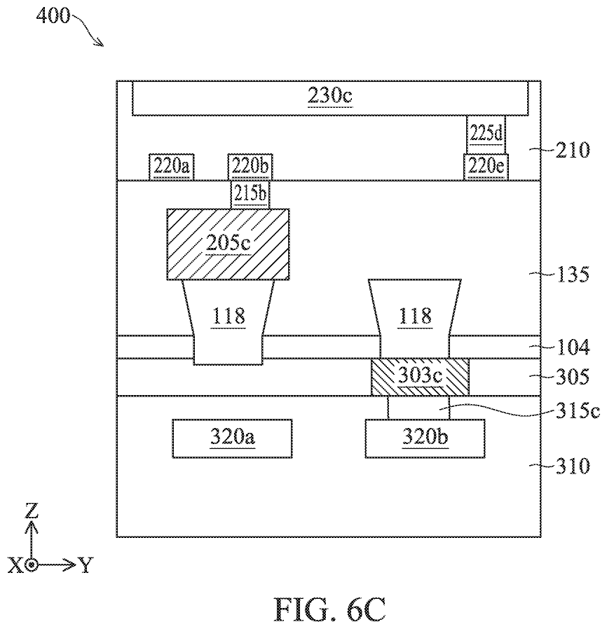

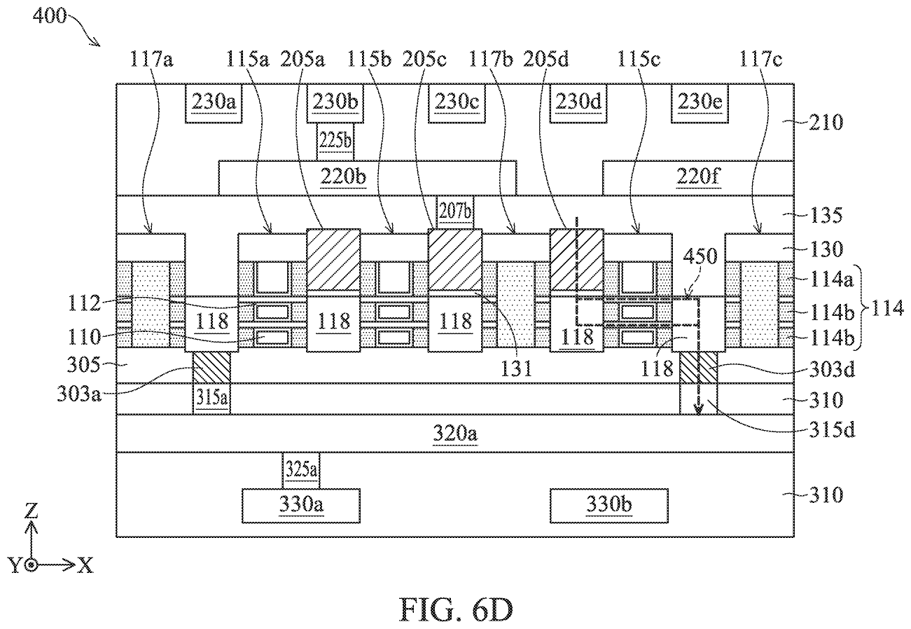

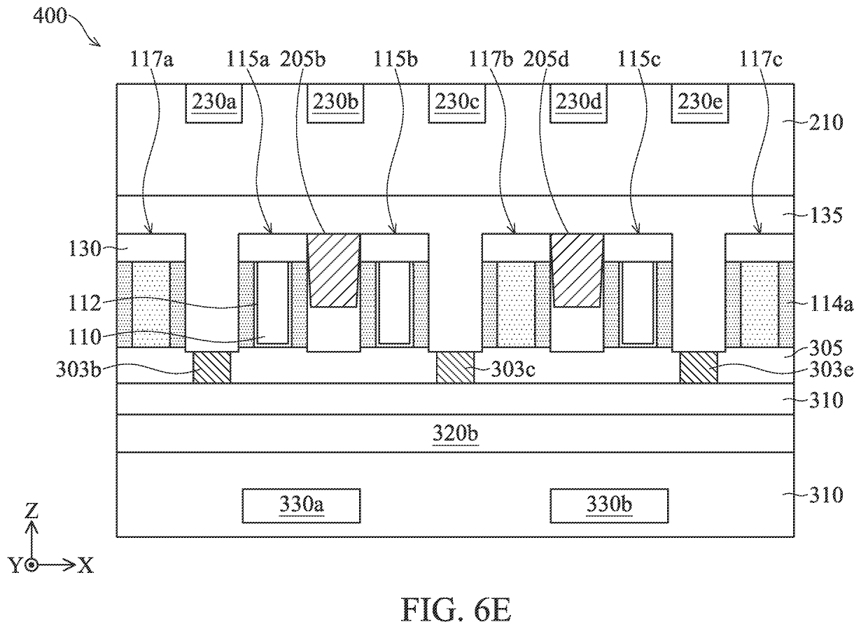

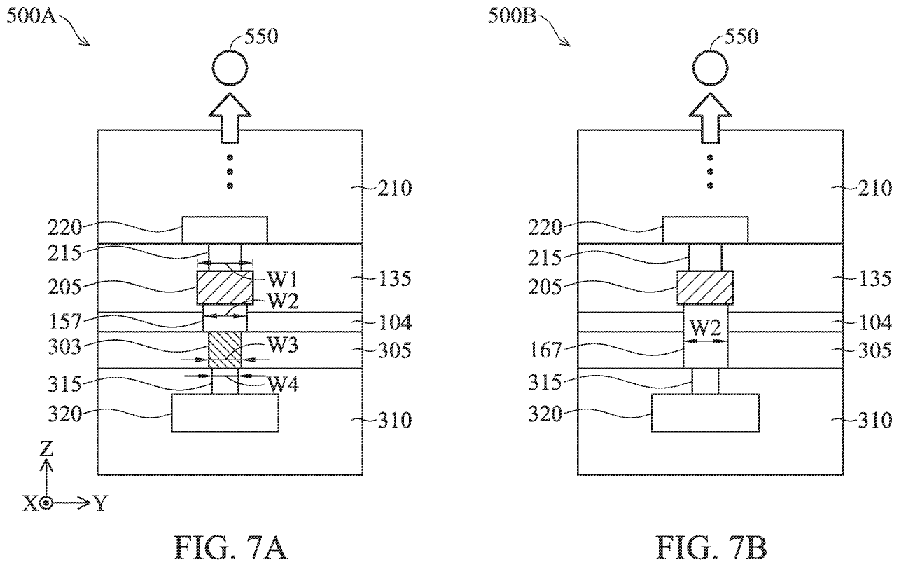

FIG. 6A shows a cross sectional view of the semiconductor device 400 along a line A-AA in FIGS. 5A and 5B, in accordance with some embodiments of the disclosure. FIG. 6B shows a cross sectional view of the semiconductor device 400 along a line B-B in FIGS. 5A and 5B, in accordance with some embodiments of the disclosure. FIG. 6C shows a cross sectional view of the semiconductor device 400 along a line C-CC in FIGS. 5A and 5B, in accordance with some embodiments of the disclosure. FIG. 6D illustrates a cross sectional view of an embodiment of the semiconductor device 400 along a line D-DD in FIGS. 5A and 5B, in accordance with some embodiments of the disclosure. FIG. 6E shows a cross sectional view of the semiconductor device 400 along a line E-EE in FIGS. 5A and 5B, in accordance with some embodiments of the disclosure.

The semiconductor device 400 may include a cell array formed by the logic cells, e.g., the standard cells (also referred to STD cells). As discussed above, the STD cells may include logic devices, including but not limited to logic circuits such as inverters, NANDs, NORs, flip-flops, SACNs or a combination thereof. For the sake of providing an example, FIG. 5A shows the two logic cells 410 and 420 arranged in a row of the cell array, and the logic cell 410 is a NAND and the logic cell 420 an inverter. It should be understood that the logic cell 410 (including the NAND) and the logic cell 420 (including the inverter) are merely examples. The present disclosure applies to other types of STD cells as well, for example cells including NORs, ANDs, ORs, flip-flops, SCANs, or a combination thereof.

The semiconductor device 400 includes the active areas 105a and 105b. The active areas 105a and 105b extend in the X-direction and have a continuous rectangular shape in the top view. The semiconductor device 400 further includes the gate structures 115a through 115c and the isolation structures 117a through 117c extending in the Y-direction. The gate structures 115a through 115c engage the active area 105a to form the N-type transistors N1 and N2 of the logic cell 410 and the N-type transistor N3 of the logic cell 420. Moreover, the gate structures 115a through 115c engage the active area 105b to form the P-type transistors P1 and P2 of the logic cell 410 and the P-type transistor P3 of the logic cell 420.

The isolation structures 117a and 117b are arranged in the boundary of the logic cell 410, and the isolation structures 117b and 117c are arranged in the boundary of the logic cell 420. The isolation structures 117a through 117c isolate the logic cells 410 and 420, other logic cells (not shown), and other devices (not shown) from each other. In such embodiment, the isolation structures 117a through 117c are dielectric-base dummy gates. In some embodiments, the logic cells in the same row of the cell array are separated from each other by the isolation structures. For example, the logic cells 410 and 420 are separated from each other by the isolation structure 117b.

In some embodiments, the dielectric-base dummy gate includes the gate material formed by the single dielectric layer or multiple layers and selected from a group consisting of SiO₂, SiOC, SiON, SiOCN, Carbon content oxide, Nitrogen content oxide, Carbon and Nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or a combination thereof.

In some embodiments, each of the isolation structures 117a through 117c is an oxide diffusion break (OD-break) structure with dielectric layers filling. In some embodiments, the OD-break structure is formed by refilling the dielectric into the OD-break region for a gate structure (e.g., the gate structures 115a through 115c). The OD-break region is disposed between the active areas 105a and 105b for each isolation structure. Moreover, each isolation structure over each active area may be an isolation transistor corresponding to a dummy gate. For example, the isolation structure over the active area 105a may be the gate structure of an N-type isolation transistor that is electrically connected to the VSS line through the front-side interconnect structure, so that the N-type isolation transistor is turned off. Furthermore, the isolation structure over the active area 105b may be the gate structure of a P-type isolation transistor that is electrically connected to the VDD line through the front-side interconnect structure, so that the P-type isolation transistor is turned off.

As shown in FIG. 6A, the gate structure 115b includes the gate dielectric layer 112 and the gate electrode 110, in which the gate dielectric layer 112 wraps around the nanostructures 120 and the gate electrode 110 wraps around the gate dielectric layer 112. The materials of the gate dielectric layer 112 and the gate electrode 110 are described above. As shown in FIGS. 5A and 5B, the gate structures 115a through 115c extend in the Y-direction. In some embodiments, each of the gate structures 115a through 115c is shared by one N-type transistor and one P-type transistor. For example, the gate structure 115b is shared by the P-type transistor P1 and the N-type transistor N1. Therefore, the gate structures 115a through 115c are also referred to as the common gates. In some embodiments, the gate structures 115a through 115c have the same gate length in the X-direction, and the gate length is about 6 nm to about 20 nm. In some embodiments, the gate structures 115a through 115c have different gate lengths in the X-direction, and the gate lengths are about 6 nm to about 20 nm.

As shown in FIGS. 6A, 6D and 6E, the gate top dielectric layers 130 are over the gate structures 115a through 115c, the isolation structures 117a through 117c, the gate spacers 114, and the nanostructures 120. The material of the gate top dielectric layers 130 is discussed above.

The gate spacers 114 are on sidewalls of the gate structures 115a through 115c and the isolation structures 117a through 117c, as shown in FIGS. 6D and 6E. The gate spacers 114 include the top spacers 114a and the inner spacers 114b. The top spacers 114a are over the nanostructures 120 and on top sidewalls of the gate structures 115a through 115c and the isolation structures 117a through 117c. The top spacers 114a may include multiple dielectric materials and be selected from a group consist of SiO₂, Si₃N₄, carbon doped oxide, nitrogen doped oxide, porous oxide, air gap, or, or a combination thereof.

The inner spacers 114b are between the nanostructures 120, as shown in FIG. 6D. The inner spacers 114b may include a dielectric material having higher K value (dielectric constant) than the top spacers 114a and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the top spacers 114a and the inner spacers 114b have a thickness in the X-direction of about 4 nm to about 12 nm.

As shown in FIGS. 5A and 5B, the gate end dielectrics 121 are at ends of the gate structures 115a through 115c and the isolation structures 117a through 117c. The gate end dielectrics 121 are used for separating the gate structures 115a through 115c and the isolation structures 117a through 117c. For example, the gate end dielectrics 121 separate the gate structures 115a through 115c from the gate structures of other logic cells (not shown). The material of the gate end dielectrics 121 is selected from a group consisting of Si₃N₄, nitride-base dielectric, carbon-base dielectric, high K material (K>=9), or a combination thereof.

The nanostructures 120 are wrapped by the gate structures 115a through 115c to serve as channels or channel layers of the P-type transistors P1 through P3 and the N-type transistors N1 through N3. As shown in FIGS. 6A and 6D, each of the P-type transistors P1 through P3 and the N-type transistors N1 through N3 has two nanostructures 120 vertically arranged (or stacked) in the Z-direction. In some embodiments, the nanostructures 120 have a channel width W in the Y-direction of about 4 nm to about 70 nm, a thickness T in the Z-direction of about 4 nm to about 10 nm, and a space distance S in the Z-direction of about 6 nm to about 20 nm, as shown in FIG. 6A. Furthermore, the nanostructures 120 have a vertical pitch P in the Z-direction of about 10 nm to about 30 nm. The vertical pitch P equals the thickness T plus the space distance S, i.e., P=T+S.

Each source/drain feature 118 is disposed between two adjacent gate structures and connect (or contact) the nanostructures 120 of the transistors, as shown in FIGS. 6B through 6D. Therefore, each source/drain feature 118 is shared by two adjacent gate structures. In some embodiments, the source/drain features 118 may be also referred to as common source/drain features. As described above, the source/drain features 118 is formed by the epitaxially-grown materials discussed above.

The active areas 105a and 150b constructed by the nanostructures 120 and source/drain features 118 remains continuity. Such continuous active areas 105a and 150b increase the stress of the channel of the transistors to improve transistor performance. More specifically, the nanostructures 120 and source/drain features 118 of the N-type transistors N1 through N3 and the nanostructures 120 of the isolation structures 117a through 117c are connected with each other to construct the continuous active area 105a. The nanostructures 120 and source/drain features 118 of the P-type transistors P1 through P3 and the nanostructures 120 of the isolation structures 117a through 117c are connected with each other to construct the continuous active area 105b.

As discussed above, the front-side interconnect structure is over the device region or at the front-side of the device region. The front-side interconnect structure of the semiconductor device 400 includes the source/drain contacts 205a through 205d, the vias 215a through 215c, the metal lines 220a through 220h, the vias 225a through 225f, the metal lines 230a through 230e, the gate vias 207a through 207c, the inter-layer dielectric (ILD) 135, and IMD 210, which are over (or at the front-side of) the P-type transistors P1 through P3 and the N-type transistors N1 through N3.

The vias 215a through 215c, the metal lines 220a through 220h, the vias 225a through 225f, the metal lines 230a through 230e, and the gate vias 207a through 207c may be respectively similar to the vias V0, the metal lines M1, the vias V1, the metal lines M2, and the via F_VG of FIG. 4. Furthermore, the source/drain contacts 205a through 205d, the vias 215a through 215c and 225a through 225f, the gate vias 207a through 207c, the metal lines 220a through 220h and 230a through 230e, the ILD 135, and IMD 210 may also be referred to as the front-side drain contacts, the front-side vias, the front-side gate vias, the front-side metal lines, the front-side ILD, and the front-side IMD, respectively.

As shown in FIG. 5A, the source/drain contacts 205a through 205d extend in the Y-direction. The metal lines 220a through 220h extend in the X-direction, and the metal lines 230a through 230e extend in the Y-direction. The source/drain contacts 205a through 205d are over and contact (or connect) the source/drain features 118, as shown in FIGS. 6B through 6E. In some embodiments, the vias 215a through 215c and 225a through 225f and the gate vias 207a through 207c may have circular shape in the top view. In other embodiments, the vias 215a through 215c and 225a through 225f and the gate vias 207a through 207c may have a rectangular shape in the top view.

The semiconductor device 400 further includes silicide features 131 between the source/drain contacts 205a through 205d and the source/drain features 118, as shown in FIG. 6D. The silicide features 131 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In the logic cell 410, the gates of the P-type transistor P1 and the N-type transistor N1 share the common gate structure 115b. The input signal IN1 is applied to the gates of the P-type transistor P1 and the N-type transistor N1 through the metal line 230a, the via 225a, the metal line 220c and the gate via 207b. The gates of the P-type transistor P2 and the N-type transistor N2 share the common gate structure 115a. The input signal IN2 is applied to the gates of the P-type transistor P2 and the N-type transistor N2 through the metal line 230c, the via 225d, the metal line 220e and the gate via 207a.

The drain nodes of the P-type transistors P1 and P2 share the source/drain contact 205a, and are coupled to the drain node of the N-type transistor N1 through the source/drain contact 205a, the via 215a, the metal line 220d, the via 225c, the metal line 230b, the via 225b, the metal line 220b, the via 215a, and the source/drain contact 205c.

As discussed above, the back-side interconnect structure is under the device region or at the back side of the device region. Referring to FIG. 5B, the back-side interconnect structure of the semiconductor device 400 includes the source/drain contacts 303a through 303e, the vias 315a through 315e, the metal lines 320a and 320b, the vias 325a and 325b, the metal line 330a and 330b, the dielectric 305 (shown in FIGS. 6A-6E), and the IMD 310 (shown in FIGS. 6A-6E), which are under (or at the back-side of) the P-type transistors P1 through P3 and the N-type transistors N1 through N3.

The vias 315a through 315e, the metal line 320a and 320b, the vias 325a and 325b, and the metal line 330a and 330b may be respectively similar to the via B_V0, the metal lines B_M1, the via B_Va, and the metal lines B_M2 discussed above. The source/drain contacts 303a through 303e, the vias 315a through 315e and 325a and 325b, the metal lines 320a and 320b and 330a and 330b, the dielectric 305, and IMD 310 may also be referred to as the back-side source contacts, the back-side vias, the back-side metal lines, the back-side dielectric layer, and the back-side IMD, respectively.

As shown in FIG. 5B, the source/drain contacts 303a through 303e extend in the Y-direction, the metal lines 320a and 320b extend in the X-direction, and the metal lines 330a and 330b extend in the Y-direction. In the semiconductor device 400, the line widths of the back-side metal lines are wider than the line widths of the front-side metal lines. For example, the widths of the metal lines 330a and 330b are greater than the widths of the active areas 105a and 105b in the Y-direction, and the widths of the metal lines 220a through 220h are less than the widths of the active areas 105a and 105b in the Y-direction.

By arranging the VDD and VSS voltage metal lines in the back-side interconnect structure to reduce the routing loading in the front-side interconnection structure, thereby improving circuit density for the logic cells. The less metal lines in the same area (layer) also benefits the metal conductor resistance-capacitance (RC) performance (can be set for either Lower Resistance (wider width) or lower capacitance (larger space), or both), so as to decrease the RC delay and power IR drop.

In the logic cells 410 and 420, the drain nodes of the transistors are connected to the corresponding nodes through the front-side interconnect structure, and the source nodes of the some transistors are connected to the corresponding VDD and VSS lines through the back-side interconnect structure. Therefore, the current flows through the front-side drain contact, the drain feature 118, the channel regions of the nanostructures 120, the source feature 118 and then to the back-side source contact, as shown in label 450 in FIG. 6D.

In should be noted that the sheet number is two (i.e., each transistor has two channels), as shown in FIG. 6D, so as to have lower channel height for capacitance reduction (e.g., the capacitance between the source/drain and gate), and shallower source/drain depth for both source/drain resistance and current crowing reduction, thereby decreasing the expected current crowding and source/drain high resistance issues.

As shown in FIG. 6C through 6E, the source/drain contacts 303a through 303e are under and contact (or connect) the source/drain features 118. The source/drain contacts 303a, 303c and 303e are used to contact the source node (i.e., the source/drain features 118) of the P-type transistors P1 through P3, and the source/drain contacts 303b and 303d are used to contact the source node (i.e., the source/drain features 118) of the N-type transistors N2 and N3. In some embodiments, the back-side contact 303a through 303e are formed by performing lithography and dielectric etch to expose the source/drain features 118, and then the contact metal material deposition and CMP are performed. Furthermore, for the exposed source/drain features 118 of the N-type transistors N1 through N3, extra doping is used to form the source/drain features 118, such as P31 or As, or Ge, or combination species doping. Moreover, for the exposed source/drain features 118 of the P-type transistors P1 through P3, extra doping is used to form the source/drain features 118, such as B11, or BF2, or Ge, or combination species doping. In some embodiments, the extra doping species includes Ge implant for the source/drain features 118 of the P-type and N-type transistors.

In other words, compared with the source/drain features 118 connected to the front-side contact, the source/drain features 118 connected to the back-side contact further include the additional implant. The additional implant may be the N+ species implant for N-type GAA transistor, and the additional implant may be the P+ species implant for P-type GAA transistor. By adding extra doping species, the impedance (or resistance) the back-side source contacts are decreased, and the source/drain features 118 are also decreased.

In some embodiments, the vias 325a and 325b may have a circular shape in the top view. In other embodiments, the vias 325a and 325b may have a rectangular shape in the top view. In some embodiments, the vias 315a through 315e may have a rectangular or an elliptical shape in the top view. The dimension ratio of the vias 315a through 315e is the ratio of the long side to the short side, and the dimension ratio is about 1.2 to about 5.

The back-side interconnect structure of the semiconductor device 400 are used for providing voltage to the circuit cells 410 and 420. In such embodiment, the metal lines 320a and 320b are respectively connected to a VDD voltage source and a VSS voltage source (not shown). Therefore, the metal line 320a may be also referred to as the power line, the VSS line, the (back-side) VSS voltage metal line, the (back-side) VSS voltage line, or (back-side) VSS voltage conductor, and the metal line 320b may be also referred to as the power line, the VDD line, the (back-side) VDD voltage metal line, the (back-side) VDD voltage line, or (back-side) VDD voltage conductor.

The source/drain contacts 303a through 303c, and the vias 315b and 315c are used for the logic cell 410. The source/drain contact 303a is under and contact (or connect to) the source/drain feature 118 of the N-type transistor N2, and the via 315a is configured to connect the source/drain contact 303a to the metal line 320a. Therefore, the VSS voltage is supplied to the source node of the N-type transistor N2 through the metal line 320a, the via 315a, and the source/drain contact 303a.

The source/drain contact 303b is under and contact (or connect to) the source/drain feature 118 of the P-type transistor P2, and the via 315b is configured to connect the source/drain contact 303b to the metal line 320b. Similarly, the source/drain contact 303c is under and contact (or connect to) the source/drain feature 118 of the P-type transistor P1, and the via 315c is configured to connect the source/drain contact 303c to the metal line 320b. Therefore, the VDD voltage is supplied to the source node of the P-type transistors P1 and P2 through the metal line 320b, the vias 315b and 315c, and the source/drain contacts 303b and 303c.

The source/drain contacts 303d and 303e, and the vias 315d and 315e are used for the logic cell 420. The source/drain contact 303d is under and contact (or connect to) the source/drain feature 118 of the N-type transistor N3, and the via 315d is configured to connect the source/drain contact 303d to the metal line 320a. Therefore, the VSS voltage is supplied to the source node of the N-type transistor N3 through the metal line 320a, the via 315d, and the source/drain contact 303d. The source/drain contact 303e is under and contact (or connect to) the source/drain feature 118 of the P-type transistor P3, and the via 315e is configured to connect the source/drain contact 303e to the metal line 320b. Therefore, the VDD voltage is supplied to the source node of the P-type transistor P3 through the metal line 320b, the via 315e, and the source/drain contact 303e.

The ILD 135, the IMD 210, the dielectric 305, and the IMD 310 may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the source/drain contacts 205a through 205d, the vias 215a through 215c, the metal lines 220a through 220h, the vias 225a through 225f, the metal lines 230a through 230e, the gate vias 207a through 207c, the source/drain contacts 303a through 303e, the vias 315a through 315e, the metal lines 320a and 320b, the vias 325a and 325b, the metal line 330a and 330b are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

In some embodiments, the source/drain contacts 205a through 205d and the source/drain contacts 303a through 303e are formed in respective contact layers. The contact layers include single metal material or multiple metal layers. The material of the contact layers are selected from a group consist of Ti, TiN, Pt, W (tungsten) layer, or Co (Cobalt) layer, or Ru (Ruthenium), or W, or Ir (Iridium), or Rh (rhodium), TaN, Cu, or a combination thereof.

The metal line 320a is connected to VSS voltage source to serve as the VSS voltage line or the VSS voltage conductor, and the metal line 320b is connected to VDD voltage source to serve as the VDD voltage line or the VDD voltage conductor. In some embodiments, the metal lines 320a and 302b continuously extend in the X-direction, and will be connected to the corresponding voltage sources in an area other than the area where logic cells are located.

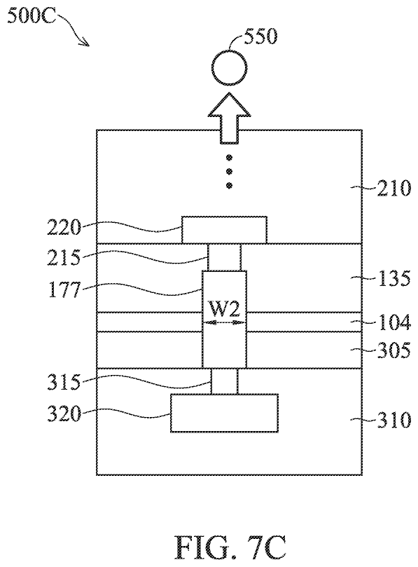

FIGS. 7A through 7C shows cross sectional views of the connection structures (or power tap structure) 500A through 500C for connecting the VDD or VSS voltage line of the back-side interconnect structure to the VDD or VSS voltage source of the front-side interconnect structure, in accordance with some embodiments of the disclosure.

In FIG. 7A, the connection structure 500A may connect the back-side voltage line 320 to the front-side power source 550 (VDD or VSS). The back-side voltage line 320 may be the metal line B_M2 discussed above. The connection structure 500A includes a back-side via 315, a back-side contact feature 303, a tap via 157, a front-side contact feature 205, a front-side via 215, and a front-side metal line 220. The power source 550 is over the logic cells as discussed above or the front-side metal line 220. The tap via 157 is formed between the back-side contact feature 303 and the front-side contact feature 205.

In the Y-direction, the back-side via 315 has a width W4, and the back-side contact feature 303 has a width W3 that is greater than the width W4. Furthermore, the tap via 157 has a width W2 that is greater than the width W3, and the contact feature 205 has a width W1 that is greater than the width W2.

In FIG. 7B, the connection structure 500B is similar to the connection structure 500A of FIG. 7A, except that the back-side contact feature 303 is omitted. A tap via 167 is formed between the back-side via 315 and the front-side contact feature 205. In other words, the depth of the tap via 167 is greater than the depth of the tap via 157 of FIG. 7A in the Z-direction. Furthermore, the depth of the tap via 167 is greater than the depth of the back-side contact feature 303 of FIG. 7A in the Z-direction.

In FIG. 7C, the connection structure 500C is similar to the connection structure 500A of FIG. 7A, except that the back-side contact feature 303 and the front-side contact feature 205 are omitted. A tap via 177 is formed between the back-side via 315 and the front-side via 215. In other words, the depth of the tap via 177 is greater than the depth of the tap via 167 of FIG. 7B in the Z-direction. Furthermore, the depth of the tap via 177 is greater than the depth of the back-side contact feature 303 of FIG. 7A in the Z-direction. Moreover, the depth of the tap via 177 is greater than the depth of the front-side contact feature 205 of FIG. 7B in the Z-direction.

Embodiments of semiconductor devices are provided. The semiconductor devices includes the logic cells. In each logic cell, the source nodes of the transistors having two channel members are connected to the back-side power conductor through the back-side source contact, and the drain nodes of the transistors having two channel members are coupled to the front-side conductors through the front-side drain contact. Therefore, the metal arrangement in the front-side interconnect structure and the back-side interconnect structure is more flexible, thereby decreasing the routing loading and increasing circuit density for ICs with high density and high speed.

In some embodiments, a semiconductor device is provided. The semiconductor device includes a logic cell in a device region, a back-side interconnect structure on a back-side of the device region, and a front-side interconnect structure on a front-side of the device region. The logic cell includes a P-type gate-all-around (GAA) nanosheet transistor and an N-type GAA nanosheet transistor. Each of the P-type and N-type GAA nanosheet transistors has two channel members vertically stacked in the device region. The back-side interconnect structure includes a first back-side contact and a second back-side contact, a VDD line formed in a back-side metal layer and coupled to a source feature of the P-type GAA nanosheet transistor through the first back-side contact, and a VSS line formed in the back-side metal layer and coupled to a source feature of the N-type GAA nanosheet transistor through the second back-side contact. The front-side interconnect structure includes a first front-side contact, a second front-side contact and at least one signal. The metal line is coupled to a drain feature of the P-type GAA nanosheet transistor through the first front-side contact, or coupled to a drain feature of the N-type GAA nanosheet transistor through the second front-side contact.

In some embodiments, a semiconductor device is provided. The semiconductor device includes a plurality of cells arranged in a cell array of a device region, a plurality of isolation structures at cell boundaries of the cells, a back-side interconnect structure on a back-side of the device region, and a front-side interconnect structure on a front-side of the device region. Each of the cells includes at least one gate-all-around (GAA) nanosheet transistor having two channel members vertically stacked in the device region. The cells in a row of the cell array are separated from each other by the isolation structures. The back-side interconnect structure includes a power line formed in a back-side metal layer and extending in a first direction. A source feature of the GAA nanosheet transistor in each of the cells is coupled to the power line through a respective back-side contact. The front-side interconnect structure includes a plurality of front-side contacts. Each of the front-side contacts is coupled to a drain feature of the GAA nanosheet transistor in each of the cells.

In some embodiments, a semiconductor device is provided. The semiconductor device includes a logic cell in a device region, a back-side interconnect structure, and a front-side interconnect structure on a front-side of the device region. The logic cell includes a gate-all-around (GAA) nanosheet transistor. The GAA nanosheet transistor has two channel members vertically stacked in the device region. The back-side interconnect structure includes a back-side contact and a power line formed in a back-side metal layer and coupled to a source feature of the GAA nanosheet transistor through the back-side contact. The front-side interconnect structure includes a front-side contact coupled to a drain feature of the GAA nanosheet transistor. The drain feature of the GAA nanosheet transistor includes epitaxially-grown materials, and the source feature of the GAA nanosheet transistor includes the epitaxially-grown materials and an additional implant.

The foregoing outlines nodes of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a logic cell in a device region, comprising:
a P-type gate-all-around (GAA) nanosheet transistor; and
an N-type GAA nanosheet transistor;
wherein each of the P-type and N-type GAA nanosheet transistors has two channel members vertically stacked in the device region;
a back-side interconnect structure on a back-side of the device region, comprising:
a first back-side contact and a second back-side contact;
a VDD line formed in a back-side metal layer and coupled to a source feature of the P-type GAA nanosheet transistor through the first back-side contact; and
a VSS line formed in the back-side metal layer and coupled to a source feature of the N-type GAA nanosheet transistor through the second back-side contact; and
a front-side interconnect structure on a front-side of the device region, comprising:
a first front-side contact and a second front-side contact; and
at least one metal line coupled to a drain feature of the P-type GAA nanosheet transistor through the first front-side contact or coupled to a drain feature of the N-type GAA nanosheet transistor through the second front-side contact.

2. The semiconductor device as claimed in claim 1, wherein the back-side interconnect structure further comprises:
a first back-side via formed between the back-side metal layer and the back-side of the device region, wherein the VDD line is coupled to the first back-side contact through the first back-side via; and
a second back-side via formed between the back-side metal layer and the back-side of the device region, wherein the VSS line is coupled to the second back-side contact through the second back-side via;
wherein the first and second back-side vias have a rectangular shape or an elliptical shape.

3. The semiconductor device as claimed in claim 2, wherein the first and second back-side vias have a dimension ratio of long side to short side that is between 1.2 and 5.

4. The semiconductor device as claimed in claim 1, wherein the VDD line and the VSS line extend in a first direction, and a gate electrode wrapping around the two channel members of the P-type or N-type GAA nanosheet transistor extends in a second direction, wherein the first direction is perpendicular to the second direction.

5. The semiconductor device as claimed in claim 4, wherein the P-type GAA nanosheet transistor and the N-type GAA nanosheet transistor share the gate electrode.

6. The semiconductor device as claimed in claim 1, wherein the logic cell is an inverter, a NAND gate, a NOR gate, an AND gate, an OR gate, a Flip-Flop, a SCAN, or a combination thereof.

7. The semiconductor device as claimed in claim 1, further comprising:
a power tap structure, comprising:
a tap via formed in an isolation layer between the front-side interconnect structure and the back-side interconnect structure,
wherein the VDD or VSS line is coupled to a power source of the front-side interconnect structure through the tap via.

8. The semiconductor device as claimed in claim 7, wherein a depth of the tap via is greater than that of the first and second back-side contacts and the first and second front-side contacts.

9. A semiconductor device, comprising:
a plurality of cells arranged in a cell array of a device region, wherein each of the cells comprises:
at least one gate-all-around (GAA) nanosheet transistor having two channel members vertically stacked in the device region;
a plurality of isolation structures at cell boundaries of the cells, wherein the cells in a row of the cell array are separated from each other by the isolation structures,
a back-side interconnect structure on a back-side of the device region, comprising:
a power line formed in a back-side metal layer and extending in a first direction,
wherein a source feature of the GAA nanosheet transistor in each of the cells is coupled to the power line through a respective back-side contact; and
a front-side interconnect structure on a front-side of the device region, comprising:
a plurality of front-side contacts,
wherein each of the front-side contacts is coupled to a drain feature of the GAA nanosheet transistor in each of the cells.

10. The semiconductor device as claimed in claim 9, wherein the back-side interconnect structure further comprises:
a plurality of back-side vias formed between the back-side metal layer and the back-side of the device region, wherein the power line is coupled to the back-side contacts through the back-side vias,
wherein the back-side vias are rectangular or ellipse-shaped vias.

11. The semiconductor device as claimed in claim 10, wherein the back-side vias have a dimension ratio of long side to short side that is within a range of 1.2 to 5.

12. The semiconductor device as claimed in claim 9, wherein each gate electrode wrapping around the two channel members of the GAA nanosheet transistor extends in a second direction, and the first direction is perpendicular to the second direction.

13. The semiconductor device as claimed in claim 12, wherein each of the isolation structures comprises a dielectric-base dummy gate extending in the second direction.

14. The semiconductor device as claimed in claim 9, wherein each of the isolation structures is an oxide diffusion break (OD-break) structure comprising two dummy gates and a OD-break region between the dummy gates.

15. The semiconductor device as claimed in claim 9, wherein each of the logic cells is an inverter, a NAND gate, a NOR gate, an AND gate, an OR gate, a Flip-Flop, a SCAN, or a combination thereof.

16. A semiconductor device, comprising:
a logic cell in a device region, comprising:
a gate-all-around (GAA) nanosheet transistor,
wherein the GAA nanosheet transistor has two channel members vertically stacked in the device region;
a back-side interconnect structure on a back-side of the device region, comprising:
a back-side contact; and
a power line formed in a back-side metal layer and coupled to a source feature of the GAA nanosheet transistor through the back-side contact; and
a front-side interconnect structure on a front-side of the device region, comprising:
a front-side contact coupled to a drain feature of the GAA nanosheet transistor,
wherein the drain feature of the GAA nanosheet transistor comprises epitaxially-grown materials, and the source feature of the GAA nanosheet transistor comprises the epitaxially-grown materials and an additional implant.

17. The semiconductor device as claimed in claim 16, wherein when the GAA nanosheet transistor is an N-type transistor, the additional implant comprises phosphorus, Arsenic, Ge, or a combination thereof.

18. The semiconductor device as claimed in claim 16, wherein when the GAA nanosheet transistor is a P-type transistor, the additional implant comprises Boron, BF2, Ge, or a combination thereof.

19. The semiconductor device as claimed in claim 16, further comprising:
a power tap structure, comprising:
a tap via formed in an isolation layer between the front-side interconnect structure and the back-side interconnect structure,
wherein the power line is coupled to a power source of the front-side interconnect structure through the tap via.

20. The semiconductor device as claimed in claim 19, wherein a depth of the tap via is greater than that of the back-side contact and the front-side contact.
